(19) United States
(12) Patent Application Publication
(10) Pub. No.: US 2007/0184580 A1
(43) Pub. Date: Aug. 9, 2007

(54) Method of making a small substrate compatible for processing

(75) Inventors: Johan Hendrik Klootwijk, Eindhoven (NL); Cornelis Eustatius Timmering, Eindhoven (NL); Jacob Snijder, Eindhoven (NL); Ronald Dekker, Eindhoven (NL); Theodorus Martinus Michelsen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronic, N.V., Eindhoven (NL)

(21) Appl. No.: 10/597,994

(22) PCT Filed: Feb. 2, 2005
(86) PCT No.: PCT/IB05/50436

§ 371 Date: Aug. 15, 2006

(30) Foreign Application Priority Data
Feb. 19, 2004 (EP) 04100661.0

(51) Int. Cl. H01L 21/00

(52) U.S. Cl. 438/107; 257/E23.125

(57) ABSTRACT

A method of making a comparatively small substrate (12) compatible with manufacturing equipment for a larger-size standard substrate is disclosed. The standard substrate (1) has a surface (10) in which a depression (8) is formed, in which depression the small substrate is connected by means of a layer of a bonding material (13). The depression is formed so as to have a flat bottom (9) extending parallel to the surface. The depression has a depth such that, after the small substrate has been connected with its rear side to the bottom of the depression of the standard substrate by means of the layer of bonding material, the front side (14) of the small substrate forms a free surface which practically coincides with the surface (10) of the carrier wafer. When the standard substrate with the small substrate positioned in the depression is placed into a lithographic stepper, the free surface of the small substrate is placed automatically in a position such that patterns having very small dimensions can be projected onto a photoresist layer formed on said free surface.

The invention relates to a method of making a comparatively small substrate compatible for being processed in equipment designed for a larger standard substrate, wherein the standard substrate has a surface in which a cavity is formed, in which cavity the small substrate to be processed is attached by means of a layer of a bonding material.

The standard substrate is, for instance, a wafer of silicon having a diameter of 150 mm. For such silicon wafers, inter alia, lithographic equipment is available enabling semiconductor devices having very many, very small components to be manufactured. In such equipment, a wafer is automatically positioned such that patterns with details of 0.12 μm are sharply imaged, via a lens system, in a layer of photoresist provided on the surface of the wafer. Such advanced equipment is not available for wafers of semiconductor material having smaller diameters; equipment designed for smaller wafers having a diameter of for instance 100 mm, is limited, for example, to imaging of details of 0.5 μm or larger on the surface of said wafers.

Although other materials are also possible, the small substrate to be processed may be, for example, a wafer of a semiconductor material such as silicon carbide or a III-V compound such as indium phosphide or gallium arsenide; the commercially available wafers of these semiconductor materials have a much smaller diameter than the above-mentioned 150 mm. In the method set forth in the opening paragraph, the small substrate is attached in a cavity in the surface of the standard substrate, care being taken that the free surface of the small substrate facing away from the bottom of the cavity coincides substantially with the surface of the standard substrate. The small substrate can be processed in the above-mentioned advanced lithographic equipment; if the standard substrate is placed in said equipment, the free surface of the small substrate automatically is positioned such that patterns are sharply imaged in a photoresist layer provided on the surface. It is noted that the small substrate can now also be processed in other equipment designed for large silicon wafers, such as equipment for depositing layers of insulating and conductive material, for implanting ions and for testing semiconductor elements manufactured in a wafer.

U.S. Pat. No. 6,248,646 discloses a method of the type mentioned in the opening paragraph, wherein a number of cavities are formed in the surface of the standard substrate, in which cavities small substrates of crystalline silicon carbide are provided. The standard substrate is made of amorphous silicon carbide. The depth of the cavities formed is such that the small substrates provided in the cavities project above the surface of the standard substrate. The thickness of the small substrates exceeds the depth of the cavities in the standard substrate. Subsequently, the parts of the small substrates projecting above the surface are removed by means of a chemical-mechanical polishing treatment. The free surfaces thus formed of the small substrates then coincide with the surface of the standard substrate.

A drawback of the known method resides in that a top layer of the small substrates projecting above the surface of the standard substrate is removed by the chemical-mechanical polishing treatment. As a result, said method is unsuitable for processing small substrates which have already been provided, on their front side, with special top layers, such as thin metal layers or epitaxially grown layers. Particularly for the manufacture of semiconductor devices in wafers of II-VI and III-V semiconductor materials, use is made in practice of wafers which are provided on the front side with a number of layers that are epitaxially grown on top of one another. To form bipolar transistors, for example, in succession, an n-type collector layer of indium gallium arsenic, a layer of indium phosphide, a p-type base layer of indium gallium arsenic, a layer of indium phosphide and an emitter contact layer of n-type indium gallium arsenic are epitaxially grown on a wafer of indium phosphide.

It is an object of the invention to provide, inter alia, a method in which said drawback is obviated. To achieve this, the method mentioned in the opening paragraph is characterized in accordance with the invention in that the cavity in the standard substrate is formed so as to have a flat bottom, which extends parallel to the surface, and a depth such that, after the small substrate is attached with its rear side to the bottom of the cavity in the surface of the standard substrate by means of said layer of bonding material, the front side of said small substrate forms the free surface which substantially coincides with the surface of the standard substrate. As the front side of the small substrate forms the free surface which substantially coincides with the surface of the standard substrate, the small substrate need not be subjected to surface treatments after it has been attached in the cavity, and hence can be provided, prior to being attached in the cavity, with special top layers, such as thin metal layers or epitaxially grown layers.

In customary, state-of-the-art photolithographic apparatus, referred to in short as steppers, a lens system is used to image a number of identical patterns next to each other on a layer of photoresist provided on the surface of a wafer of semiconductor material. Each time before such a pattern is imaged, the surface of the wafer is brought into a position with respect to the lens system in which this pattern is sharply imaged on the layer of photoresist. This means that the wafer is moved towards or away from the lens system over a small distance with respect to a starting position into which a wafer is arranged when it is placed in the stepper. In a PAS 5000 stepper by ASML, which is suitable for 150 mm silicon wafers, it is possible, for this purpose, to move the wafer from said starting position over approximately 30 μm in the direction of the lens system or in a direction away from the lens system. If the front side of the small substrate, which is provided in the cavity formed in the surface of the standard substrate, coincides, within these limits, with the surface of the standard substrate, then patterns can also be imaged sharply on the front side of the small substrate. The expression “substantially coincide(s)” should therefore be taken to mean “coincide(s) within certain limits”. As, in practice, the smaller substrates not only have a smaller diameter than said large silicon wafers, but also a smaller thickness, it proves to be possible in practice to form a carrier wafer of a thickness such that it can be processed in standard equipment.

The standard substrate may be made of all kinds of materials, such as the above-mentioned silicon carbide, however, it may alternatively be a standard silicon wafer. In that case, the cavity is etched in the surface situated on the front side of the wafer. It proves to be difficult to produce a cavity having a well-defined depth and a flat bottom. This problem is obviated if the standard substrate is formed by, in succession, providing a layer of silicon oxide on the front side of a standard silicon wafer, attaching the wafer with its front side covered with the silicon oxide layer onto an auxiliary substrate, subjecting the rear side of the silicon wafer to a polishing treatment in order to obtain a thickness of the wafer that corresponds to the depth of the cavity to be formed, and forming the cavity, from the polished rear side, by means of an etch treatment which stops automatically at the layer of silicon oxide. The depth is determined by the thickness of the silicon wafer after the polishing treatment; if there is started from a 150 mm silicon wafer having a thickness of 680 μm, the thickness can be reduced, within an accuracy of a few μm, to for example 320 μm, using a customary chemical-mechanical polishing treatment. As the etching process, for example in a customary KOH bath, stops automatically at the layer of silicon oxide, a cavity is obtained having a well-defined depth and a very flat bottom.

In another method of forming a carrier wafer with a cavity having a well-defined depth and a very flat bottom, the standard substrate is formed by, in succession, subjecting a standard silicon wafer to a polishing treatment from the rear side of the wafer to bring it to a thickness that corresponds to the depth of the cavity to be formed, applying a layer of silicon oxide to the polished rear side, attaching the wafer with its polished rear side covered with the layer of silicon oxide onto an auxiliary substrate, and subsequently forming the cavity from the front side of the wafer by means of an etch treatment that stops automatically at the layer of silicon oxide. In this method, no material is removed from the front side of the standard silicon wafer; this front side is left intact and forms the front side of the standard substrate.

When determining the depth of the cavity in the standard substrate, account must be taken not only of the thickness of the small substrate but also of that of the layer of bonding material used to attach the small substrate in the cavity. As the thickness of the small substrates and the thickness of the layer of bonding material can be realized only within certain tolerances, the front side of the small substrate, after attachment in the cavity, will not coincide exactly with the surface of the standard substrate. In view of the above-mentioned limits of approximately 30 μm, it is necessary, in practice, to work accurately. This can be achieved more easily, and in addition the front side of the small substrate coincides exactly with the surface of the standard substrate, if the small substrate is attached in the cavity by detachably attaching it with its flat front side onto a flat auxiliary plate, and, after the small substrate is provided at the rear side with a layer of bonding material, by pressing the auxiliary plate with the small substrate into the cavity in the surface of the standard substrate, and by removing the auxiliary plate after the adhesive has cured. In this process, a simple, detachable connection between the small substrate and the flat auxiliary plate is obtained by causing the small substrate to be sucked against the auxiliary plate by means of an underpressure.

These and other aspects of the invention are apparent from and will be elucidated with reference to the embodiments described hereinafter.

In the drawings:

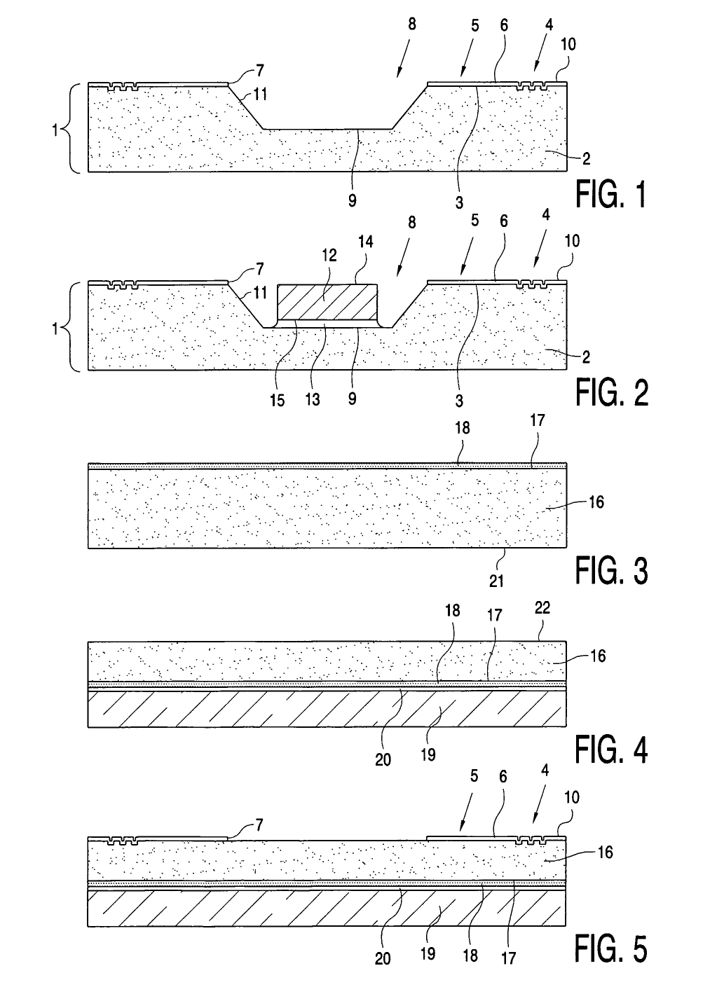

FIGS. 1 and 2 are diagrammatic, cross-sectional views of a few stages in the preparation of a comparatively small wafer to be processed in equipment suitable for processing larger standard substrates, by means of a first embodiment of the method according to the invention,

FIGS. 3 through 7 are diagrammatic, cross-sectional views of a few stages in the preparation of a comparatively small wafer to be processed in equipment suitable for processing larger standard wafers of semiconductor material, by means of a second embodiment of the method in accordance with the invention,

FIGS. 8 through 10 are diagrammatic, cross-sectional views of a few stages in the preparation of a comparatively small wafer to be processed in equipment suitable for processing larger standard wafers of semiconductor material, by means of a third embodiment of the method in accordance with the invention, and

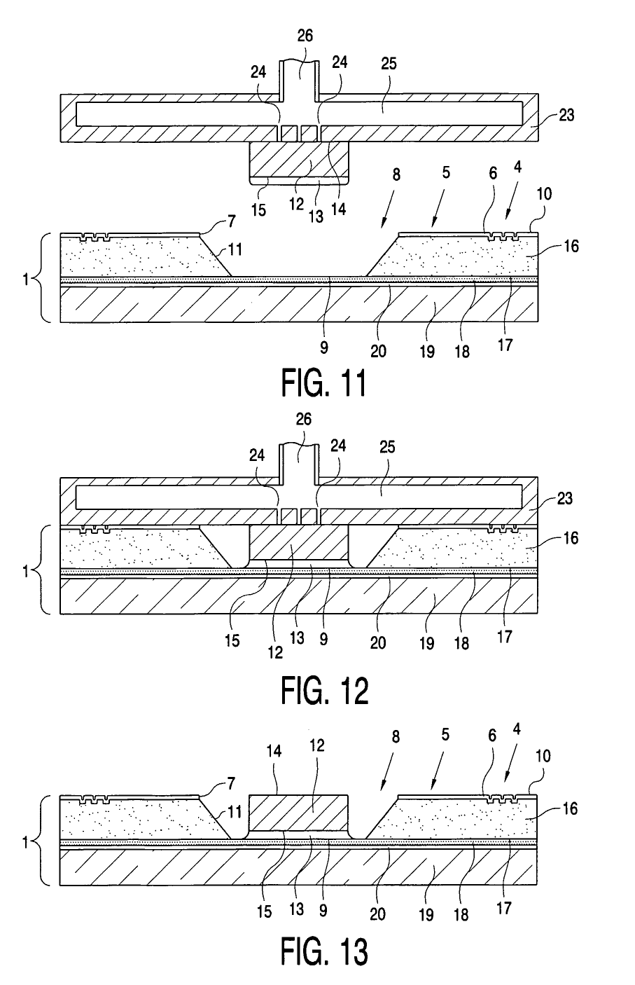

FIGS. 11 through 13 are diagrammatic, cross-sectional views of a few stages in the preparation of a comparatively small wafer to be processed in equipment suitable for processing larger standard wafers of semiconductor material, by means of a fourth embodiment of the method in accordance with the invention.

FIGS. 1 and 2 are diagrammatic, cross-sectional views, not drawn to scale, of a few stages in the preparation of a comparatively small substrate to be processed in equipment suitable for processing larger-size, standard substrates by means of a first embodiment of the method in accordance with the invention. The Figures show the preparation of a single, small substrate, however, it will be clear that, in more cavities, the standard substrate may accommodate more small substrates.

In this first embodiment of the method, as shown in FIG. 1, a standard substrate 1 is formed, use being made of a standard silicon wafer 2 having a diameter of 150 mm and a thickness of approximately 680 μm as the starting material. A surface 3 of the wafer 2 is subsequently provided with aligning characteristics 4 and an etch mask 5, which is formed in an approximately 120 nm thick silicon nitride layer 6 deposited on the surface 3. The etch mask 5 is provided with a window 7. After the formation of the etch mask, an approximately 320 μm deep cavity 8 is etched in the surface 3 of the silicon wafer 2, in a customary KOH solution, said cavity having a flat bottom 9 which extends parallel to the surface 2, and walls 11 which include an angle of 57° with the bottom 9. The standard substrate 1 thus formed comprises a flat surface 10, formed by the surface of the silicon nitride layer 6, in which surface 10 a cavity 8 is formed. The thickness of the silicon nitride layer 6 is so small, compared to the depth of the cavity 8, that it plays no further role.

As shown in FIG. 2, the small substrate 12 to be processed, in this case an indium phosphide wafer having a diameter of 20 mm and a thickness of 300 μm, is attached in the cavity 8 by means of an approximately 20 μm thick layer of a bonding material 13 which is to be applied to the bottom of the cavity. In this process, it is made sure that the free surface 14 of the small wafer 12, which free surface faces away from the bottom 9, substantially coincides with the surface 10 of the standard substrate 1. For this purpose, the cavity 8 formed in the standard substrate 1 has a depth such that, after the small substrate 12 has been attached with its rear side 15 onto the bottom 9 of the cavity 8 in the surface 10 of the standard substrate 1 by means of the layer of bonding material 13, the front side 14 of said small substrate constitutes a free surface which is to be processed and which substantially coincides with the surface 10 of the standard substrate 1.

As the front side 14 of the small substrate 12 constitutes a free surface which coincides substantially with the surface 10 of the standard substrate 1, the small substrate 12 does not require further surface treatments after it has been attached in the cavity 8. Consequently, before it is attached in the cavity, the small substrate can be provided with special top layers, such as thin metal layers or epitaxially grown layers. The small substrate 12, in this example made of indium phosphide, is provided at its surface with a number of epitaxially grown layers.

The standard substrate 1 has dimensions, in this example, which are equal to those of a standard silicon wafer having a diameter of 150 mm. For such silicon wafers, inter alia, lithographic equipment is available that permits patterns having details of 0.12 μm to be sharply imaged via a lens system in a photoresist layer provided on the surface of the wafers. By virtue of the fact that the front side 14 of the small substrate 12 coincides with the surface 10 of the standard substrate 1, said front side 14 of the small substrate 12 is automatically arranged in such a position, when the standard substrate 1 is placed in said photolithographic equipment, that patterns are sharply imaged in a layer of photoresist provided on the surface 10, 14.

In customary, state-of-the-art photolithographic steppers, a number of identical patterns are imaged next to each other on a photoresist layer by means of a lens system, which photoresist layer is provided on the surface of a wafer of semiconductor material. Each time before such a pattern is imaged, the surface of the wafer is brought into a position with respect to the lens system in which this pattern is sharply imaged on the photoresist layer. In this process, the wafer is moved towards or away from the lens system over a small distance with respect to a starting position into which a wafer is brought when it is placed in the stepper. In a PAS 5000 stepper by ASML, which is suitable for 150 mm silicon wafers, the wafer can, for this purpose, be moved from said starting position over approximately 30 μm in the direction of the lens system or in a direction away from the lens system. If the front side 14 of the small substrate 12 coincides, within these limits, with the surface 10 of the standard substrate 1, then patterns are also automatically sharply imaged on the front side 14 of the small substrate 12 attached in the cavity 8. The alignment characteristics 4 present in the surface 10 of the standard substrate 1 enable the standard substrate 1 to be aligned in said lithographic equipment, so that in the case of a number of such alignment operations to be carried out successively, the patterns on the front side 14 of the small substrate 12 are imaged in a correct position with respect to each other. As the surface 10 of the standard substrate 1 and the front side 14 of the small substrate 12 coincide, the front side 14 of the small substrate 12 does not have to be provided with alignment characteristics for this purpose. By virtue thereof, precious space on the front side 14 of the small substrate 12 is saved.

As both the diameter and the thickness of the small substrate 12 are smaller than the diameter and the thickness of said large silicon wafers, which, at a diameter of 150 mm, have a thickness of approximately 600 μm, it is possible to form a carrier wafer having a thickness such that it can be processed in standard equipment.

FIGS. 3 through 7 diagrammatically show a second embodiment of the method, wherein the standard substrate 1 is formed, as shown in FIG. 3, by providing a standard silicon wafer 16 at its front side 17 with an approximately 200 nm thick silicon oxide layer 18, in this example a layer of silicon oxide grown using a customary thermal process. As shown in FIG. 4, this wafer 16 is attached with its front side 17 covered with said silicon oxide layer 18 onto an auxiliary substrate 19 by means of an adhesive layer 20, in this example an approximately 300 μm thick glass disk having the same diameter as the silicon wafer 16. Subsequently, the silicon wafer 16 is brought to a thickness that corresponds to the depth of the cavity 8 to be formed, in this example a thickness of 320 μm, by subjecting its rear side 21 to a customary chemical-mechanical polishing treatment.

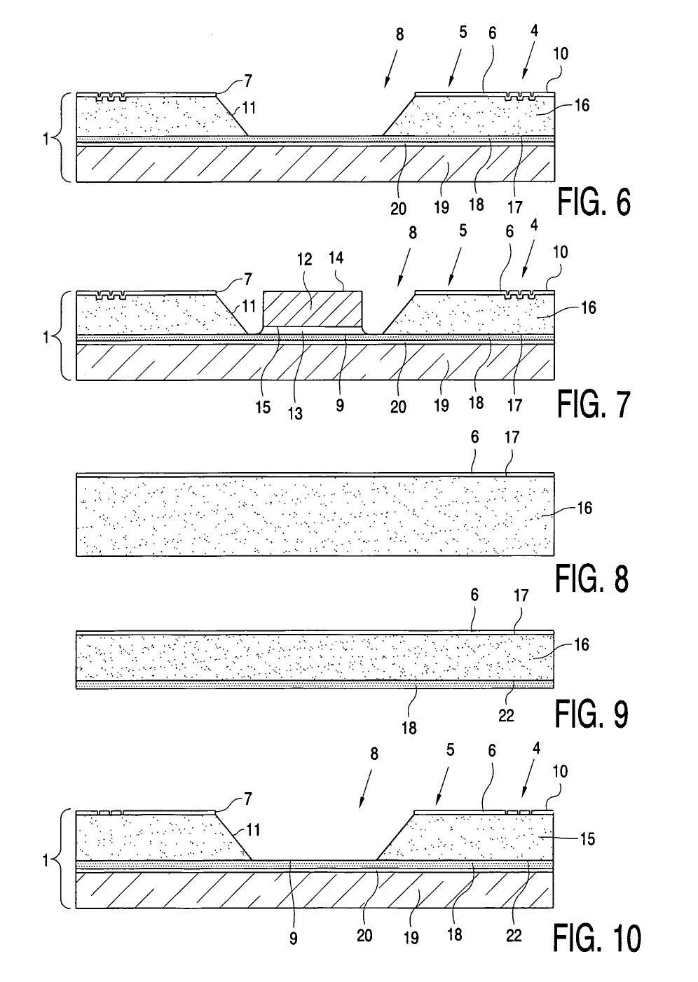

On the thus polished rear side 22 of the silicon wafer 16, alignment characteristics 4 and an etch mask 5 are subsequently formed, analogously to the first example and as shown in FIG. 5, in an approximately 120 nm thick silicon nitride layer 6 deposited on the rear side 22. The etch mask 5 is provided with a window 7 at the location of the cavity 8 to be formed. The cavity 8 is subsequently etched in a customary KOH solution. The etching process stops automatically as soon as the layer of silicon oxide 16 is exposed; the bottom 9 of the cavity 8 is formed by the silicon oxide layer 16. In this manner, as shown in FIG. 6, a cavity 8 is formed having a very flat bottom 9 and walls 11 which include an angle of 57° with the bottom 9.

The small substrate 12 is subsequently attached in the formed cavity 8 by means of an approximately 20 μm thick bonding layer 13. In this example, the bonding material used is a UV-curable glue. This glue can be exposed to UV radiation through the glass disk 18. In practice, glass disks of many different types of glass are available, so that a type of glass can be chosen whose coefficient of expansion practically matches that of the material of the small substrate 12. The standard substrate 1 with the small wafer 12 provided in the cavity thereof can then be subjected without problems to temperature treatments; differences in expansion could cause the small substrate to break or become detached from the standard substrate. In particular the above-mentioned wafers of II-V material are very fragile.

FIGS. 8 through 10 diagrammatically show a third embodiment of the method, wherein the standard substrate is formed, as shown in FIG. 8, by first providing a standard silicon wafer 16, at its front side 17, with the approximately 120 nm thick layer of silicon nitride 6 in which the etch mask 5 will be formed at a later stage. Prior to the provision of the silicon oxide layer 18, the silicon wafer 16 is brought to the desired thickness of 320 nm by means of a polishing treatment. Subsequently, the polished rear side 22 is provided with the silicon oxide layer 18, in this example an approximately 200 nm thick silicon oxide layer is deposited in a customary manner on the side 22. The wafer 16 is subsequently attached, as described in the previous example, to the glass plate 19 by means of the adhesive layer 20 on the side 22 covered with the silicon oxide layer 18. Subsequently, alignment characteristics 4 and the etch mask 5 are formed in the silicon nitride layer 6. Next, the cavity 8 is etched in the wafer 1 in the same manner as described in the previous example. The small substrate 12 is attached in the cavity 8 in the same manner as described in the previous example. In this case, the front side of the standard wafer is left intact.

When determining the depth of the cavity 8 in the standard substrate 1, account must be taken, in the examples described above, not only of the thickness of the small substrate 12 but also of the thickness of the layer of bonding material 13 by means of which the small substrate 12 is attached in the cavity 8. As the thickness of the small substrates 12 and the thickness of the layer of bonding material 13 are known only within certain tolerances, the front side 14 of the small substrate 12, after attachment of the latter in the cavity 8, will not coincide exactly with the surface 10 of the standard substrate 1. In view of the above-mentioned limits of approximately 30 μm, this means that, in practice, accuracy is required. FIGS. 11 through 13 show a fourth embodiment of the method, wherein the small substrate 12 is attached in the cavity 8 such that the front side 14 of the small substrate 12 coincides exactly with the surface 10 of the standard substrate 1. The small substrate 12 is attached in the cavity 8 by detachably attaching the small substrate 12 with its flat front side 14 onto a flat auxiliary plate 23. In this example, a simple detachable connection between the small substrate 12 and the flat auxiliary plate 23 is used; the auxiliary plate 23 is provided, in this case, with ducts 24 and a space 25 in which an underpressure can be generated via a line 26, so that the small substrate 12 can be sucked against the auxiliary plate 23. Subsequently, as shown in FIG. 12, a layer of bonding material 13, in this case UV curable glue, is applied to the rear side 15 of the small substrate 12, after which the auxiliary plate 23 is pressed onto the surface 10 of the standard substrate 1, the small substrate 12 then being situated in the cavity 8. After the glue has been cured by exposure to UV radiation, the auxiliary plate 23 is removed. The front side 14 of the clay wafer 12 now exactly coincides with the surface 10 of the standard substrate 1.

1. A method of making a comparatively small substrate compatible for being processed in equipment designed for a larger standard substrate, wherein the standard substrate has a surface in which a cavity is formed, in which cavity the small substrate to be processed is attached by means of a layer of a bonding material, characterized in that the cavity in the standard substrate is formed so as to have a flat bottom, which extends parallel to the surface, and a depth such that, after the small substrate is attached with its rear side to the bottom of the cavity in the surface of the standard substrate by means of said layer of bonding material, the front side of said small substrate forms the free surface which substantially coincides with the surface of the standard substrate.

2. A method as claimed in claim 1, characterized in that the standard substrate is formed by, in succession, providing a layer of silicon oxide on the front side of a standard silicon wafer, attaching the wafer with its front side covered with the silicon oxide layer onto an auxiliary substrate, subjecting the rear side of the silicon wafer to a polishing treatment in order to obtain a thickness of the wafer that corresponds to the depth of the cavity to be formed, and forming the cavity, from the polished rear side, by means of an etch treatment which stops automatically at the layer of silicon oxide.

3. A method as claimed in claim 1, characterized in that the standard substrate is formed by, in succession, subjecting a standard silicon wafer to a polishing treatment from the rear side of the wafer to bring it to a thickness that corresponds to the depth of the cavity to be formed, applying a layer of silicon oxide to the polished rear side, attaching the wafer with its polished rear side covered with the layer of silicon oxide onto an auxiliary substrate, and subsequently forming the cavity from the front side of the wafer by means of an etch treatment that stops automatically at the layer of silicon oxide.

4. A method as claimed in claim 2, characterized in that the small substrate is attached in the cavity by detachably attaching the small substrate with its flat front side onto a flat auxiliary plate, and, after the small substrate is provided at its rear side with a layer of bonding material, by pressing the auxiliary plate with the small substrate into the cavity in the surface of the standard substrate, and by removing the auxiliary plate after the adhesive has cured.

5. A method as claimed in claim 4, characterized in that the small substrate is detachably attached onto the auxiliary plate by causing the small substrate to be sucked against the auxiliary plate.

6. A method as claimed in claim 2, characterized in that the silicon wafer is glued with its front side covered with the silicon oxide layer onto a glass plate that serves as an auxiliary substrate.

7. A method as claimed in claim 6, characterized in that an UV-curable glue is used as the bonding material.

8. A method as claimed in claim 2, characterized in that the silicon wafer is provided at its polished rear side with aligning characteristics for automatically aligning the standard substrate in photolithographic equipment.

9. A method as claimed in claim 2, characterized in that the silicon wafer is provided at its polished rear side with an etch mask formed in a silicon nitride layer deposited on the polished side.
